(19) United States
(12) Patent Application Publication
(10) Pub. No.: US 2012/0146101 A1
(43) Pub. Date: Jun. 14, 2012

(54) MULTI-GATE TRANSISTOR DEVICES AND MANUFACTURING METHOD THEREOF

(76) Inventor: Chun-Hsien Lin, Tainan County (TW)

(21) Appl. No.: 12/965,933

(22) Filed: Dec. 13, 2010

(51) Int. Cl. H01L 29/04; H01L 21/336

(52) U.S. Cl. 257/255; 438/198; 257/E21.437; 257/E29.004

(57) ABSTRACT

A method for manufacturing multi-gate transistor devices includes providing a semiconductor substrate having a first patterned hard mask for defining at least a first fin formed thereon, forming the first fin having a first crystal plane orientation on the semiconductor substrate, forming a second patterned hard mask for defining at least a second fin on the semiconductor substrate, forming the second fin having a second crystal plane orientation that is different from the first crystal plane orientation on the semiconductor substrate, forming a gate dielectric layer and a gate layer covering a portion of the first fin and a portion of the second fin on the semiconductor substrate, and forming a first source/drain in the first fin and a second source/drain in the second fin, respectively.

### BACKGROUND OF THE INVENTION

1. Field of the Invention

The invention relates to a method for manufacturing multi-gate transistor devices, and more particularly, to a method for manufacturing multi-gate transistor devices having different crystal plane orientations.

2. Description of the Prior Art

There are always ongoing efforts in the semiconductor industry to improve device performance and to reduce power consumption. Therefore it is always in need to keep improving device performance in the semiconductor processing art.

### SUMMARY OF THE INVENTION

According to a first aspect of the present invention, there is provided a method for manufacturing multi-gate transistor devices. The method includes providing a semiconductor substrate having a first patterned hard mask for defining at least a first fin formed thereon, forming the first fin having a first crystal plane orientation on the semiconductor substrate, forming a second patterned hard mask for defining at least a second fin on the semiconductor substrate, forming the second fin having a second crystal plane orientation that is different from the first crystal plane orientation on the semiconductor substrate, forming a gate dielectric layer and a gate layer covering a portion of the first fin and a portion of the second fin on the semiconductor substrate, and forming a first source/drain in the first fin and a second source/drain in the second fin, respectively.

According to a second aspect of the present invention, there is provided a multi-gate complementary metal-oxide-semiconductor (CMOS) device. The multi-gate CMOS device includes a semiconductor substrate, a first fin having a first crystal plane orientation formed on the semiconductor substrate, a second fin having a second crystal plane orientation that is different from the first crystal plane orientation formed on the semiconductor substrate, and a gate layer and a gate dielectric layer covering a portion of the first fin and a portion of the second fin on the semiconductor substrate.

According to the multi-gate transistor devices and the manufacturing method provided by the present invention, the first fin having the first crystal plane orientation and the second fin having the second crystal plane orientation are respectively formed on the semiconductor substrate. The first crystal plane orientation can be (100) orientation that is favorable for improving the carrier mobility of the n-channel MOS transistor while the second crystal plane orientation can be (110) orientation that is favorable for improving the carrier mobility of the p-channel MOS transistor. Accordingly, the method for manufacturing multi-gate transistor devices provided by the present invention is more preferable to provide a CMOS device of superior performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 and FIGS. 5-8 are schematic drawings illustrating the method for manufacturing multi-gate transistor devices provided by a first preferred embodiment of the present invention, wherein FIG. 8 is a cross-sectional view taken along line A-A′ in FIG. 7;

FIGS. 4-8 are schematic drawings illustrating the method for manufacturing multi-gate transistor devices provided by a second preferred embodiment of the present invention, wherein FIG. 8 is a cross-sectional view taken along line A-A′ in FIG. 7;

FIG. 9A is a circuit diagram of a typical 6T-SRAM cell; and

FIG. 9B is a schematic drawing illustrating a layout of the 6T-SRAM cell.

### DETAILED DESCRIPTION

Please refer to FIGS. 1-3 and FIGS. 5-8, which are schematic drawings illustrating the method for manufacturing a multi-gate transistor devices provided by a first preferred embodiment of the present invention. As shown in FIG. 1, the preferred embodiment first provides a semiconductor substrate 200. The semiconductor substrate 200 includes a silicon-on-insulator (SOI) substrate. It is well-known to those skilled in the art that the SOI substrate upwardly includes a silicon substrate 202, a bottom oxide (BOX) layer 204, and a semiconductor layer such as a silicon layer 206 formed on the BOX layer 204. The silicon layer 206 comprises (100) crystal plane orientation. However, for providing superior ground connection and thermal dissipation and for reducing interference and cost, the semiconductor substrate 200 provided by the preferred embodiment also can include a bulk silicon substrate. As shown in FIG. 1, a patterned hard mask 210a for defining at least a fin of a multi-gate transistor device is formed on the semiconductor substrate 200.

Please still refer to FIG. 1. After forming the patterned hard mask 210a, a first etching process is performed to etching the silicon layer 206 of the semiconductor substrate 200 through the patterned hard mask 210a. Consequently, at least a fin 212a is obtained. The fin 212a includes a pair of sidewalls 214a opposite to each other as shown in FIG. 1. It is noteworthy that the first etching process is a dry etching in the preferred embodiment. The dry etching process includes sulfur hexafluoride (SF₆) or nitrogen trifluoride (NF₃). The dry etching process etches the silicon layer 206 anisotropically. Therefore the sidewalls 214a of the fin 212a are perpendicular to the semiconductor substrate 200. In other words, a cross-sectional view of the fin 212a includes a rectangular shape as shown in FIG. 1. More important, the sidewalls 214a of the fin 212a includes a first crystal plane orientation after the dry etching process, and the first crystal plane orientation is (100) orientation in the preferred embodiment.

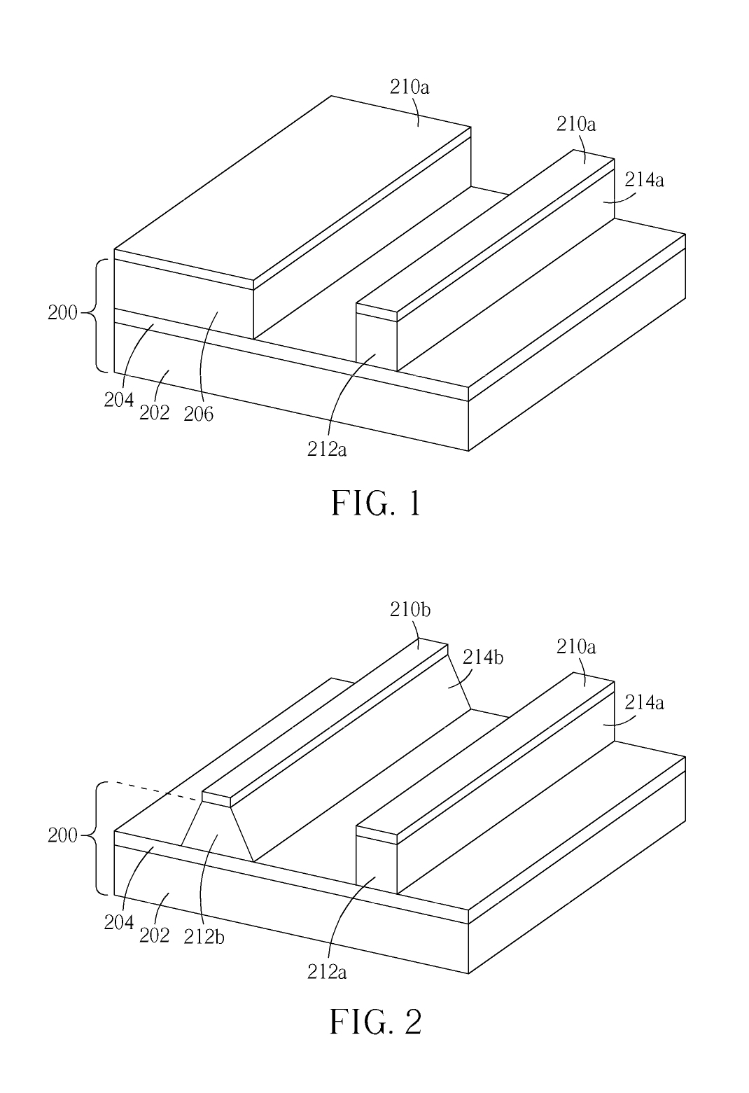

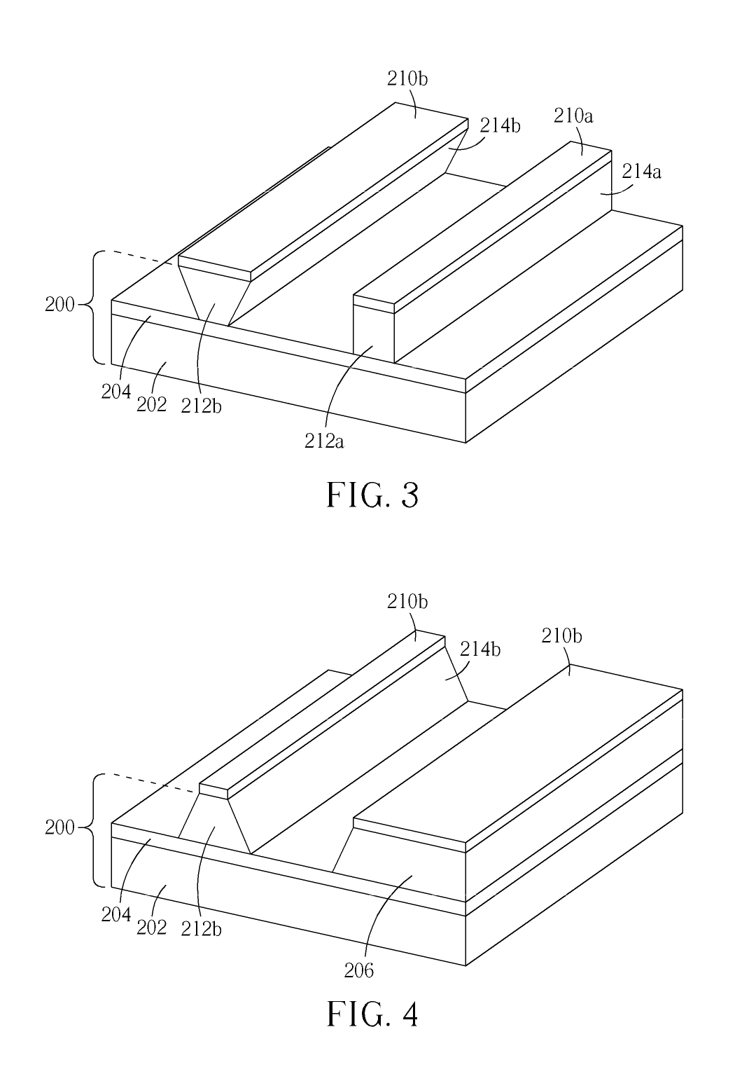

Please refer to FIG. 2 and FIG. 3. Next, a patterned hard mask 210b for defining at least a fin of a multi-gate transistor device is formed on the semiconductor substrate 200. As shown in FIG. 2 and FIG. 3, the patterned hard mask 210a and the patterned hard mask 210b are co-planar. A second etching process is subsequently performed to etch the semiconductor substrate 200 through the patterned hard mask 210b, thus at least a fin 212b is formed. Those skilled in the art would easily realize that a protecting layer, such as the photoresist used to define the patterned hard mask 210b, is used to protect the fin 212a from the second etching process in the preferred embodiment. It is noteworthy that the second etching process includes a wet etching in the preferred embodiment. For example, the wet etching process provided by the preferred embodiment includes ammonium hydroxide (NH₄OH) solution. A ratio between NH₄OH and H₂O is 1:X and a quantity of X is smaller than 250. The wet etching process provided by preferred embodiment also includes tetramethylammonium hydroxide (TMAH) solution and a concentration of the TMAH is lower than 2.5%. Furthermore, in the preferred embodiment, the wet etching process is performed at a temperature between 20-60° C. The wet etching process etches the silicon layer isotropically, thus a sidewalls 214b of the fin 212b is not perpendicular to the semiconductor substrate 200. In detail, a cross-sectional view of the fin 212b includes a trapezoid as shown in FIG. 2 or an inverted trapezoid as shown in FIG. 3. More important, the sidewalls 214b of the fin 212b includes a second crystal plane orientation that is different from the first crystal plane orientation of the sidewalls 214a of the fin 212a after the wet etching process. The second crystal plane orientation is (110) orientation in the preferred embodiment.

Furthermore, the second etching process preferably includes a two-stepped etching process in the preferred embodiment: First, a dry etching process including SF₆ and/or NF₃ is performed to anisotropically etch the silicon layer 206 to form the fin 212b with the sidewalls of the fin 212b are perpendicular to the semiconductor substrate 200. Then, a wet etching process including NH₄OH solution or TMAH solution is performed to isotropically etch the sidewalls of the fin 212b that are perpendicular to the semiconductor substrate 200. Consequently, the sidewalls 214b that is slanted on the semiconductor substrate 200 as shown in FIG. 3 and FIG. 4 are obtained. As mentioned above, the cross-sectional view of the fin 212b includes a trapezoid or an inverted trapezoid after the wet etching process, and the sidewalls 214b of the fin 212b obtain the second crystal plane orientation that is different from the first crystal plane orientation of the sidewalls 214a of the fin 212a. In the preferred embodiment, the second crystal plane orientation lane orientation is (110) orientation.

Please refer to FIG. 4, which is a schematic drawing illustrating a method for manufacturing multi-gate transistor devices provided by a second preferred embodiment of the present invention. In the second preferred embodiment, the first etching process includes the one-stepped wet etching process or the two-stepped etching process as mentioned above. The first etching process etches the silicon layer 206 through the patterned hard mask 210b, thus the fin 212b of which a cross-sectional view includes a trapezoid or an inverted trapezoid is formed on the semiconductor substrate 200. And the sidewalls 214b of the fin 212b includes a crystal plane orientation, that is (110) orientation in the preferred embodiment.

In the second preferred embodiment, the second etching process is a dry etching process, and the dry etching process is performed to etch the silicon layer 206 through the patterned hard mask 210a. Consequently, the fin 212a is formed on the semiconductor substrate 200. As mentioned above, since the dry etching process etches the silicon layer 206 anisotropically, the obtained sidewalls 214a of the fin 212a are perpendicular to the semiconductor substrate 200. In other words, the cross-sectional view of the fin 212a includes a rectangular shape. More important, the sidewalls 214a of the fin 212a includes a crystal plane orientation that is (100) orientation after the dry etching process.

Please refer to FIGS. 5-8. It is noteworthy that after forming the fin 212a and the fin 212b, the steps disclosed by the first preferred embodiment and the second preferred embodiment are identical, therefore those steps are described hereinafter. As shown in FIG. 5, a dielectric layer (not shown), a gate forming layer (not shown) and a patterned hard mask 216 are sequentially formed on the semiconductor substrate 200 after forming the first fin 212a and the second fin 212b. Then the dielectric layer and the gate forming layer are patterned to form a gate dielectric layer 218 and a gate layer 220 on the semiconductor substrate 200. The gate dielectric layer 218 and the gate layer 220 cover a portion of the fin 212a and a portion of the fin 212b. As shown in FIG. 5, an extension direction of the gate dielectric layer 218 and the gate layer 220 is perpendicular to an extension direction of the fin 212a and the fin 212b. And the gate dielectric layer 218 and the gate layer 220 cover a portion of the sidewalls 214a of the fin 212a and a portion of the sidewalls 214b of the fin 212b. The gate dielectric layer 218 includes the conventional dielectric material such as silicon oxide (SiO), silicon nitride (SiN), or silicon oxynitride (SiON). In the preferred embodiment, the gate dielectric layer 218 can further include high-K dielectric material such as hafnium oxide (HfO), hafnium silicate (HfSiO), or metal oxide or metal silicate exemplarily of aluminum (Al), zirconium (Zr), lanthanum (La), but not limited to this. In addition, when the gate dielectric layer 218 of the preferred embodiment adopts the high-K dielectric material, the present invention can be further integrated to the metal gate process. Therefore control gate competent to the high-K gate dielectric layer is obtained. Accordingly, the gate layer 212 can include different materials according to the gate-first or gate-last process. For example, when the preferred embodiment is integrated to the gate-first process, the gate layer 220 includes metal such as tantalum (Ta), titanium (Ti), ruthenium (Ru), molybdenum (Mo), alloys of the aforementioned metals, metal nitride such as tantalum nitride (TaN), titanium nitride (TiN), molybdenum nitride (MoN), or metal carbide such as tantalum carbide (TaC). It is noteworthy that the metals are chosen by providing proper work function to the multi-gate transistors of different conductivity types. And the gate layer 220 can be a single-layered or multi-layered structure. When the preferred embodiment is integrated to the gate-last process, the gate layer 220 serves as a dummy gate and includes semiconductor material such as polysilicon.

Moreover, because top portions of the fin 212a and the fin 212b are respectively covered by the patterned hard mask 210a and the patterned hard mask 210b in the preferred embodiment, no channel regions are formed nearby. In other words, the channel regions are formed in the sidewalls 214a of the fin 212a covered by only the gate layer 220 and the gate dielectric layer 218 and in the sidewalls 214b of the fin 212b cover by only the gate layer 220 and the gate dielectric layer 218. Accordingly, the multi-gate transistor device provided by the preferred embodiment is a double-gate transistor device. More important, since the sidewalls 214a covered by the gate layer 220 and the gate dielectric layer 218 includes (100) orientation, it improves carrier mobility of an nMOS transistor. And since the sidewalls 214b covered by the gate layer 220 and the gate dielectric layer 218 includes (110) orientation, it improves carrier mobility of a pMOS transistor.

Additionally, the patterned hard mask 210a, 210b can be removed after forming the fin 212a, 212b. Thus the following formed multi-gate transistor device is a tri-gate transistor device. It should be noted that though the crystal plane orientation of the top portions is different from that of the sidewalls of the fin 212b after removing the patterned hard mask 210b, the (110) orientation in the sidewalls 214b of the fin 212b still improves the carrier mobility of the pMOS transistor device.

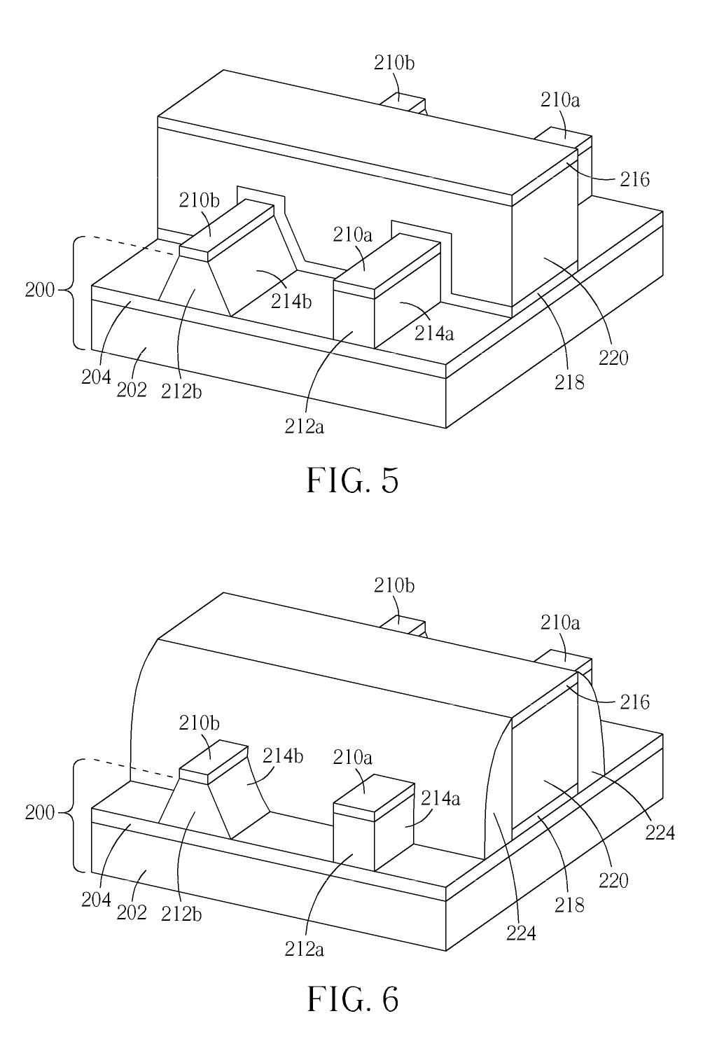

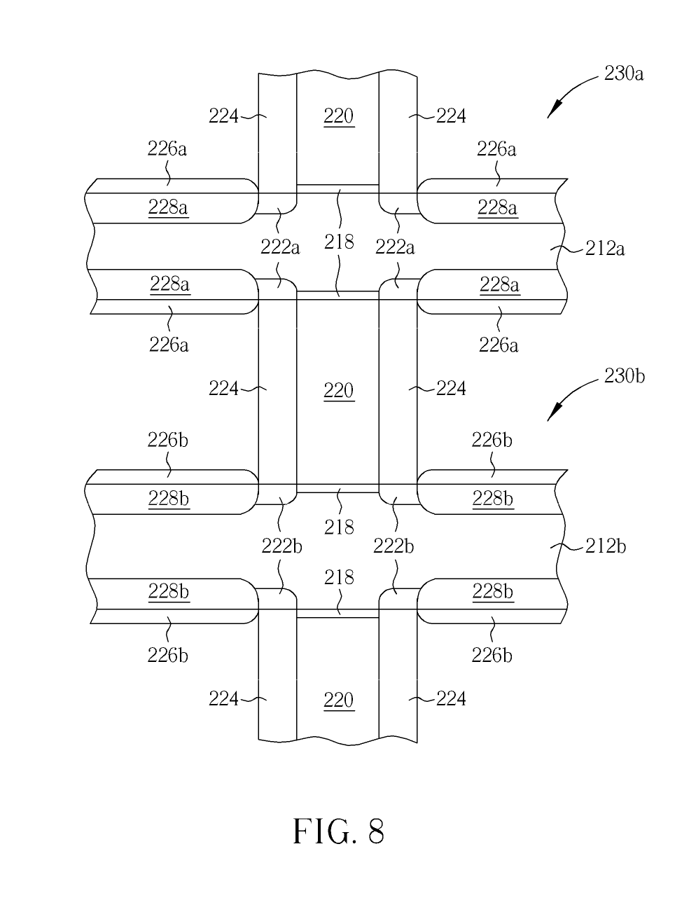

Please refer to FIG. 6. After forming the gate dielectric layer 218 and the gate layer 220, tilted ion implantations are performed form n-type lightly-doped drains (LDDs) 222a (shown in FIG. 8) in the fin 212a and p-type LDDs 222b in the fin 212b (also shown in FIG. 8). It is noteworthy that since the sidewalls 214a of the fin 212a includes (100) orientation that is favorable to improvement to the nMOS transistor and the sidewalls 214b of the fin 212b include (110) orientation that is favorable to improvement to the pMOS transistor, the n-type LDDs 222a are formed in the fin 212a and the p-type LDDs 222b are formed in the fin 212b. After forming the n-type LDDs 222a and the p-type LDDs 222b, spacers 224 are formed on sidewalls of the gate layer 220 and the gate dielectric layer 218. The spacers 224 include single-layered or multi-layered structure.

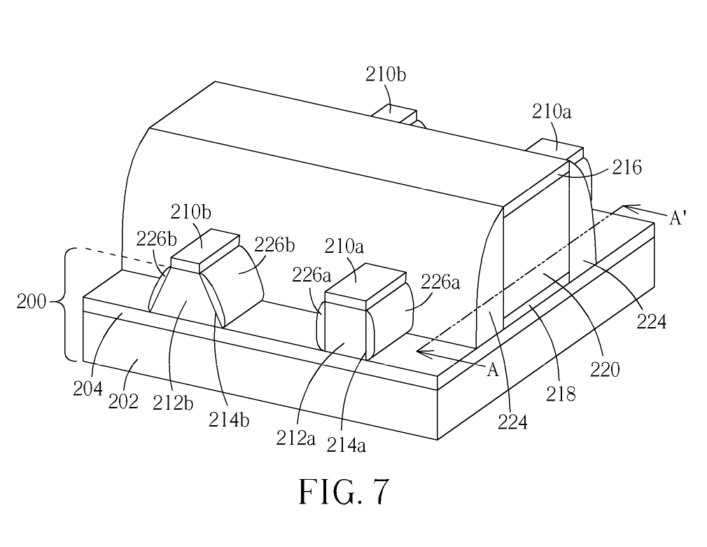

Please refer to FIG. 7. After forming the spacers 224, selective epitaxial growth (SEG) processes are performed to respectively form an epitaxial layer 226a on the sidewalls 214a of the fin 210a and an epitaxial layer 226b on the sidewalls 214b of the fin 210b not covered by the patterned hard mask 210a, 210b and 216. As mentioned, since the sidewalls 214a of the fin 212a includes (100) orientation that is favorable to improvement to the nMOS transistor and the sidewalls 214b of the fin 212b include (110) orientation that is favorable to improvement to the pMOS transistor, the epitaxial layer 226a is formed to include SiC and the epitaxial layer 226b is formed to include SiGe. The epitaxial layer 226a, 226b include materials having lattice constant different from the silicon layer 206 for providing strain stress respectively to the following formed nMOS transistor device and the pMOS transistor device. Additionally, recesses (not shown) can be selectively formed in the sidewalls 214a of the fin 210a and the sidewalls 214b of the fin 210b. Thus the epitaxial layers 226a/226b formed from the recesses are able to provide strain stress to the following formed nMOS transistor device and pMOS transistor device more efficiently.

Please refer to FIG. 8, which is a cross-sectional view taken along line A-A′ in FIG. 7. Then, ion implantations are respectively performed to form an n-type source/drain 228a in the fin 212a and a p-type source/drain 228b in the fin 212b. As mentioned above, since the sidewalls 214a of the fin 212a includes (100) orientation that is favorable to improvement to the nMOS transistor and the sidewalls 214b of the fin 212b include (110) orientation that is favorable to improvement to the pMOS transistor, the n-type source/drain 228a are formed in the fin 212a and the p-type source/drain 228b are formed in the fin 212b. Additionally, the ion implantations can be performed before the SEG processes. Furthermore, the dopants for forming the n-type source/drain 228a and the p-type source/drain 228b can be in-situ doped during performing the SEG process, and thus the ion implantation and the required anneal treatment can by further economized. As shown in FIG. 8, after forming the n-type source/drain 228a and the p-type source/drain 228b, an nMOS transistor 230a and a pMOS transistor 230b, which construct a CMOS device, are obtained.

According to the method for manufacturing multi-gate transistor devices provided by the present invention, the channel region of the pMOS transistor device 230b is formed on (110) orientation that is obtained by etching the silicon layer 205 by the wet etching process while the channel region of the nMOS transistor device 230a is formed on (100) orientation that is obtained by the dry etching process. Therefore both of carrier mobility of the nMOS transistor device 230a and the pMOS transistor device 230b are improved. As shown in FIG. 7, the method for manufacturing multi-gate transistor devices provided by the present invention is more preferably used to form a CMOS device that includes the nMOS transistor and the pMOS transistor.

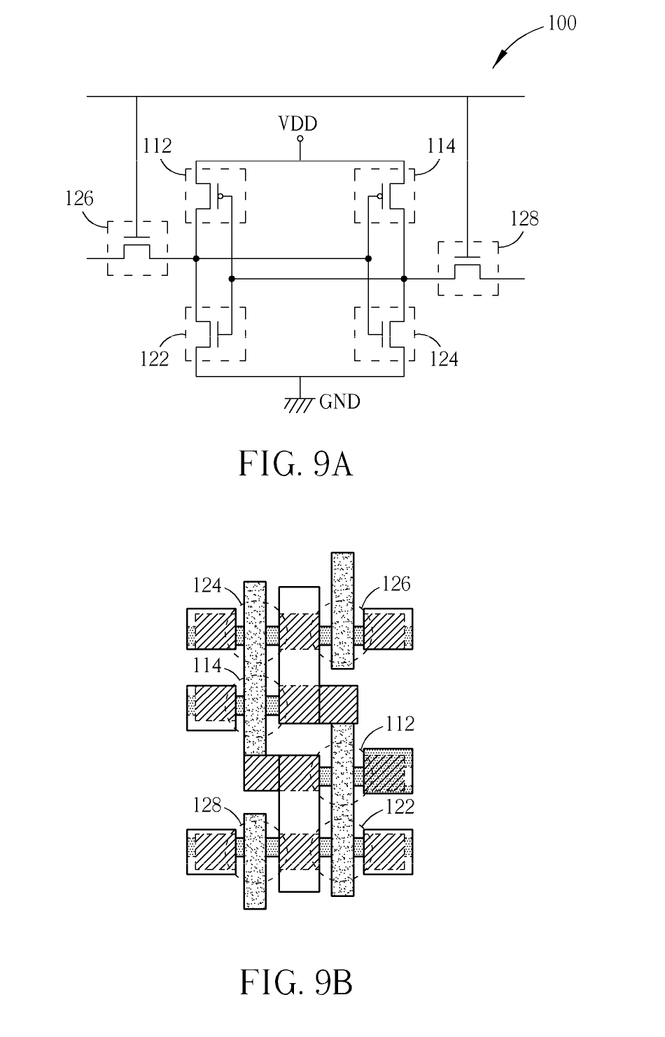

Please refer to FIGS. 9A-9B, wherein FIG. 9 is a circuit diagram of a typical 6T-SRAM cell; and FIG. 9B is a schematic drawing illustrating a layout of the 6T-SRAM cell. A typical 6T-SRAM cell 100 includes two pMOS transistors 112/114 serving as pull-up transistors, two nMOS transistors 122/124 serving as pull-down transistors, and two nMOS transistors 126/128 serving as access transistors. The pMOS transistor 112 and the nMOS transistor 122 are electrically connected in series, and the pMOS transistor 114 and the nMOS transistor 124 are electrically connected in series, and the transistors 112, 114, 122, 124 constitute a latch for storing data. As shown in FIG. 9A and 9B, according to the method for manufacturing multi-gate transistor devices provided by the present invention, the gate layer 220 serves as the gate of the pMOS transistor 112 and of the nMOS transistor 122 that are electrically connected in series, the nMOS transistor 230a serves as the pull-down transistor 122 and the pMOS transistor 230b serves as the pull-up transistor 112 accordingly. In the same concept, the gate layer 220 serves as the gate of the pMOS transistor 114 and of the nMOS transistor 124 that are electrically connected in series, the nMOS transistor 230a serves as the pull-down transistor 124 and the pMOS transistor 230b serves as the pull-up transistor 114 accordingly. As mentioned above, since the channel region of the pMOS transistor device 230b is formed on (110) orientation and the channel region of the nMOS transistor device 230a is formed on (100) orientation, the performance of both of the transistors, that is the performance of the CMOS device and the SRAM cell is impressively improved.

After forming the nMOS transistor 230a and the pMOS transistor 230b, a silicide process is performed to a silicide (not shown) respectively on the epitaxial layer 226a and the epitaxial layer 226b for reducing sheet resistance of the n-type source/drain 228a and the p-type source/drain 228b. Then, an inter-layer dielectric (ILD) layer (not shown) is formed on the semiconductor substrate 200. As mentioned above, when the preferred embodiment is integrated to the gate-last metal gate process, the gate layer 220 serving as the dummy gate is removed after forming the ILD layer, and metals provides different work functions for nMOS or pMOS transistor and metals having good gap fill characteristics are provided to form the metal gates. In addition, a post metal anneal (PMA) treatment can be introduced to adjust the work function of the metals. The preferred embodiment also can be integrated to a high-K last process. Specifically speaking, the gate dielectric layer 218 is removed subsequent to the removal of the gate layer 220 and followed by sequentially forming another gate dielectric layer having high-K dielectric material and the metal gates.

After forming the metal gates, the ILD layer is removed and followed by forming a contact etch stop layer (CESL) or a strain stress layer on the nMOS transistor 230a, the pMOS transistor 230b and the semiconductor substrate 200. In other words, the present invention can be integrated to selective strain scheme (SSS) for further improving the performance of the nMOS transistor 230a and the pMOS transistor 230b by rendering proper strain stress. And after constructing the SSS, another ILD layer (not shown) is formed on the semiconductor substrate 200, and contact holes (not shown) are formed in the ILD layer for exposing the source/drain 228a/228b. It is noteworthy that to avoid adverse impacts to the silicide during forming the metal gates and the PMA treatment, the silicide process can be performed after removing the ILD layer, or forming the CESL or the stress layer. The silicide process even can be performed after re-forming the ILD layer and forming the contact holes.

Since the abovementioned processes are well-known to those skilled in the art, the details are omitted herein in the interest of brevity.

According to the multi-gate transistor devices and the manufacturing method provided by the present invention, the first fin having the first crystal plane orientation and the second fin having the second crystal plane orientation are respectively formed on the semiconductor substrate by proper etching processes. The first crystal plane orientation is (100) orientation that is favorable for improving the carrier mobility of the n-channel MOS transistor while the second crystal plane orientation is (110) orientation that is favorable for improving the carrier mobility of the p-channel MOS transistor. In other words, carrier mobility of the nMOS transistor and the pMOS transistor are both improved by providing favorable crystal plane orientation respectively. Accordingly, the method the method for manufacturing multi-gate transistor devices provided by the present invention is more preferable to provide CMOS device of superior performance.

Those skilled in the art will readily observe that numerous modifications and alterations of the device and method may be made while retaining the teachings of the invention.

What is claimed is:

1. A method for manufacturing multi-gate transistor devices, comprising:
providing a semiconductor substrate having a first patterned hard mask for defining at least a first fin formed thereon;
forming the first fin having a first crystal plane orientation on the semiconductor substrate;
forming a second patterned hard mask for defining at least a second fin on the semiconductor substrate;
forming the second fin having a second crystal plane orientation that is different from the first crystal plane orientation on the semiconductor substrate;
forming a gate dielectric layer and a gate layer on the first fin and the second fin, the gate dielectric layer and the gate layer covering a portion of the first fin and a portion of the second fin; and
forming a first source/drain in the first fin and a second source/drain in the second fin, respectively.

2. The method for manufacturing multi-gate transistor devices according to claim 1, wherein the first crystal plane orientation is (100) orientation.

3. The method for manufacturing multi-gate transistor devices according to claim 2, further comprising a step of performing a dry etching process to form the first fin.

4. The method for manufacturing multi-gate transistor devices according to claim 3, wherein the dry etching process comprises sulfur hexafluoride (SF₆) or nitrogen trifluoride (NF₃).

5. The method for manufacturing multi-gate transistor devices according to claim 1, wherein the second crystal plane orientation is (110) orientation.

6. The method for manufacturing multi-gate transistor devices according to claim 5, further comprising a step of performing at least a wet etching process to form the second fin.

7. The method for manufacturing multi-gate transistor devices according to claim 6, wherein the wet etching process at least comprises ammonium hydroxide (NH₄OH) solution or tetramethylammonium hydroxide (TMAH) solution.

8. The method for manufacturing multi-gate transistor devices according to claim 5, a cross-sectional view of the second fin comprises a trapezoid or an inverted trapezoid.

9. The method for manufacturing multi-gate transistor devices according to claim 1, wherein the second fin is formed after forming the first fin.

10. The method for manufacturing multi-gate transistor devices according to claim 1, wherein the first fin is formed after forming the second fin.

11. The method for manufacturing multi-gate transistor devices according to claim 1, wherein the first patterned hard mask and the second patterned hard mask are co-planar.

12. The method for manufacturing multi-gate transistor devices according to claim 1, further comprising steps of forming first lightly-doped drains (LDDs) in the first fin and forming second LDDs in the second fin.

13. The method for manufacturing multi-gate transistor devices according to claim 12, further comprising a step of forming a spacer on a sidewall of the gate layer after forming the first LDDs and the second LDDs.

14. The method for manufacturing multi-gate transistor devices according to claim 1, further comprising steps of forming a first epitaxial layer in the first fin and forming a second epitaxial layer in the second fin.

15. A multi-gate complementary metal-oxide-semiconductor (CMOS) device comprising:
a semiconductor substrate;
a first fin having a first crystal plane orientation formed on the semiconductor substrate;
a second fin having a second crystal plane orientation that is different from the first crystal plane orientation formed on the semiconductor substrate; and
a gate layer and a gate dielectric layer covering a portion of the first fin and a portion of the second fin formed on the semiconductor substrate.

16. The multi-gate CMOS device of claim 15, wherein the first plane orientation is (100) orientation and the second plane orientation is (11) orientation.

17. The multi-gate CMOS device of claim 16, wherein a cross-sectional view of the first fin comprises a rectangle and a cross-sectional view of the second fin comprises a trapezoid or an inverted trapezoid.

18. The multi-gate CMOS device of claim 15, wherein the first fin further comprises a plurality of first LDDs formed therein and the second fin further comprises a plurality of second LDDs formed therein.

19. The multi-gate CMOS device of claim 15, wherein the first fin further comprises a plurality of first sources/drains formed therein and the second fin further comprises a plurality of second sources/drains formed therein.

20. The multi-gate CMOS device of claim 15, further comprises a spacer formed on sidewalls of the gate layer and the gate dielectric layer.

21. The multi-gate CMOS device of claim 15, wherein the first fin further comprises a plurality of first epitaxial layers formed thereon and the second fin further comprises a plurality of second epitaxial layers formed thereon.

22. The multi-gate CMOS device of claim 15, wherein the gate layer comprises a semiconductor material or a metal material.

23. The multi-gate CMOS device of claim 15, wherein an extension direction of the gate layer and the gate dielectric layer is perpendicular to an extension direction of the first fin and the second fin.
